(19) United States
(12) Patent Application Publication
(10) Pub. No.: US 2015/0200265 A1
(43) Pub. Date: Jul. 16, 2015

(54) SOLDER-CONTAINING SEMICONDUCTOR DEVICE, MOUNTED SOLDER-CONTAINING SEMICONDUCTOR DEVICE, PRODUCING METHOD AND MOUNTING METHOD OF SOLDER-CONTAINING SEMICONDUCTOR DEVICE

(71) Applicant: Sumitomo Electric Industries, Ltd., Osaka-shi (JP)

(72) Inventors: Tetsuya Kumano, Osaka-shi (JP); Susumu Yoshimoto, Osaka-shi (JP)

(21) Appl. No.: 14/420,129

(22) PCT Filed: Apr. 15, 2014
(86) PCT No.: PCT/JP2014/060682

§ 371 Date: Feb. 6, 2015

(30) Foreign Application Priority Data
Apr. 16, 2013 (JP) 2013-085802

(51) Int. Cl. H01L 29/47; H01L 21/285; H01L 23/00

(52) U.S. Cl. CPC H01L 29/475; H01L 24/03; H01L 24/05; H01L 24/89; H01L 21/28581; H01L 2924/10323; H01L 2924/10325; H01L 2924/1033; H01L 2924/10334; H01L 2924/10341; H01L 2924/10344; H01L 2924/10346; H01L 2924/10355; H01L 2924/10356; H01L 2924/10357; H01L 2924/10358; H01L 2924/12032; H01L 2924/13064; H01L 2924/20106; H01L 2924/014; H01L 2924/0105; H01L 2924/01047; H01L 2924/01029; H01L 2924/01083; H01L 2924/01049; H01L 2924/05442; H01L 2924/05042; H01L 2224/05075; H01L 2224/05169; H01L 2224/80801

(57) ABSTRACT

A solder-containing semiconductor device includes a semiconductor device. The semiconductor device includes a substrate, at least one group III nitride semiconductor layer disposed on the substrate, a Schottky electrode disposed on the group III nitride semiconductor layer, and a pad electrode disposed on the Schottky electrode. The pad electrode has a multi-layer structure including at least a Pt layer. The solder-containing semiconductor device further includes a solder having a melting point of 200 to 230° C. and being disposed on the pad electrode of the semiconductor device. Thereby, the solder-containing semiconductor device including the Schottky electrode, the pad electrode disposed on the Schottky electrode and the solder disposed on the pad electrode can be mounted to offer a mounted solder-containing semiconductor device without degrading the semiconductor device properties.

### TECHNICAL FIELD

The present invention relates to a solder-containing semiconductor device, a mounted solder-containing semiconductor device, a producing method and a mounting method of the solder-containing semiconductor device.

### BACKGROUND ART

In recent years, due to excellent semiconductor properties of group III nitride semiconductors, there has been proposed a semiconductor device including a substrate, a group III nitride semiconductor layer and a Schottky electrode (an electrode in Schottky contact with the semiconductor layer. The same meaning holds hereinafter), such as a Schottky barrier diode (abbreviated as SBD hereinafter) and a high electron mobility transistor (abbreviated as HEMT hereinafter).

For example, Japanese Patent Laying-Open No. 2008-177537 (PTD 1) discloses a SBD in which a Schottky metal layer formed on a group III nitride semiconductor layer is bonded to a conductive substrate, with a metal bonding layer interposed therebetween. In such SBD, the metal bonding layer and the conductive substrate are bonded through an Au—Sn eutectic wafer bonding process using an Au—Sn solder.

### CITATION LIST

### Patent Document

### PTD 1: Japanese Patent Laying-Open No. 2008-177537

### SUMMARY OF INVENTION

### Technical Problem

The mounting of the SBD disclosed in Japanese Patent Laying-Open No. 2008-177537 (PTD 1) is performed by bonding the side of the conductive substrate of the SBD or the other side opposite to the side where the Schottky metal layer of the group III nitride semiconductor layer is formed to a package. In this mounting method of the SBD, there is a disadvantage that it is difficult to radiate heat generated in the group III nitride semiconductor layer.

In order to cope with such disadvantage, it is required to develop such a SBD that has a structure which makes it possible to bond the side where the Schottky metal layer of the group III nitride semiconductor layer is formed to a package, in other words, it is possible to perform the mounting through bonding the side of the Schottky electrode.

In order to enable the mounting through bonding the side of the Schottky electrode, a pad electrode is formed on the Schottky electrode which has been formed on the group III nitride semiconductor layer, and the pad electrode is needed to be bonded to the package using an Au—Sn solder.

However, if a SBD is mounted to a package by bonding the pad electrode which is formed on the Schottky electrode of the SBD through the use of the Au—Sn solder at a temperature not less than its eutectic temperature (about 280° C.), preferably at a temperature of about 340° C. for stable use, there occurs such a problem that the withstand voltage of the mounted SBD is reduced significantly compared to the unmounted SBD.

After investigating the causes of the above problem, it is found that in order to prevent the diffusion of Sn, Pt is included in the pad electrode to be bonded by a solder, and thus, if a high temperature of about 280 to 340° C. is applied to the SBD having the pad electrode formed on the Schottky electrode, since Pt in the pad electrode is hard, stress will be concentrated on electrode edges of the pad electrode and the Schottky electrode bonded thereto. In addition, since the electrode edge of the Schottky electrode is a place where an electric field is concentrated, the concentrated stress and the concentrated electric field will make a leakage current increase. Therefore, the withstand voltage of the SBD is significantly reduced.

Based on the above findings and after further investigations, the inventors of the present invention found that in mounting an SBD including a Schottky electrode and a pad electrode which is disposed on the Schottky electrode and contains Pt, it is preferable to perform the mounting by using a solder having a melting point of 200 to 230° C.

As described above, it is an object of the present invention to provide a solder-containing semiconductor device which includes a Schottky electrode disposed on a group III nitride semiconductor layer, a pad electrode disposed on the Schottky electrode and a solder disposed on the pad electrode and is capable of being mounted through the solder without degrading the semiconductor device properties, a mounted solder-containing semiconductor device, a producing method of the solder-containing semiconductor device and a mounting method thereof.

### Solution to Problem

According to one aspect of the present invention, it is provided a solder-containing semiconductor device including a semiconductor device. The semiconductor device is provided with a substrate, at least one group III nitride semiconductor layer disposed on the substrate, a Schottky electrode disposed on the group III nitride semiconductor layer, and a pad electrode disposed on the Schottky electrode. The pad electrode has a multi-layer structure including at least a Pt layer. The solder-containing semiconductor device further includes a solder having a melting point of 200 to 230° C. and being disposed on the pad electrode of the semiconductor device.

It is acceptable that the solder-containing semiconductor device according to one aspect of the present invention further includes a dielectric layer having an opening and being disposed on the group III nitride semiconductor layer, and the Schottky electrode is disposed on a portion of the group III nitride semiconductor layer that is positioned within the opening of the dielectric layer. It is acceptable that the substrate is a group III nitride substrate. It is acceptable that the substrate is a composite substrate including an underlying substrate and a group III nitride film directly or indirectly bonded to the underlying substrate. It is acceptable that the solder-containing semiconductor device includes the group III nitride film left from the composite substrate after the removal of the underlying substrate as the substrate. It is acceptable that the solder includes at least one alloy selected from the group consisting of Sn—Ag, Sn—Cu, Sn—Ag—Cu, Sn—In—Bi, Sn—Ag—Cu—Bi, and Sn—Ag—Bi—In. It is acceptable that the Pt layer has a thickness of 30 nm or more. It is acceptable that the dielectric layer includes at least one silicon compound selected from the group consisting of Si₃N₄ and SiO₂.

According to another aspect of the present invention, it is provided a mounted solder-containing semiconductor device in which the solder-containing semiconductor device according to the one aspect in the above is mounted to a package by bonding the solder of the solder-containing semiconductor device to the package.

According to yet another aspect of the present invention, it is provided a method for producing a solder-containing semiconductor device. The producing method includes a step of forming a semiconductor device. The step of forming a semiconductor device includes a sub-step of forming at least one group III nitride semiconductor layer on a substrate, a sub-step of forming a Schottky electrode on the group III nitride semiconductor layer, and a sub-step of forming a pad electrode on the Schottky electrode. The pad electrode has a multi-layer structure including at least a Pt layer The producing method further includes a step of disposing a solder having a melting point of 200 to 230° C. on the pad electrode of the semiconductor device.

In the method for producing a solder-containing semiconductor device according to one aspect of the present invention, it is acceptable that the step of forming a semiconductor device further includes a sub-step of forming a dielectric layer having an opening on the group III nitride semiconductor layer, which is performed after the sub-step of forming the group III nitride semiconductor layer and before the sub-step of forming the Schottky electrode, and the Schottky electrode is formed in the sub-step of forming the Schottky electrode on a portion of the group III nitride semiconductor layer that is positioned within the opening of the dielectric layer.

According to yet another aspect of the present invention, it is provided a method for mounting a solder-containing semiconductor device. The mounting method includes the steps of: preparing a solder-containing semiconductor device according to one aspect of the present invention; and bonding the solder of the solder-containing semiconductor device to a package at a temperature of 200 to 230° C. so as to mount the solder-containing semiconductor device.

It is acceptable that the method for mounting a solder-containing semiconductor device according to one aspect of the present invention includes the steps of: preparing a solder-containing semiconductor device according to one aspect of the present invention; bonding the solder of the solder-containing semiconductor device to a package at a temperature of 200 to 230° C. so as to mount the solder-containing semiconductor device; and removing the underlying substrate from the composite substrate of the solder-containing semiconductor device.

### Advantageous Effects of Invention

According to the present invention, it is possible to provide a solder-containing semiconductor device which includes a Schottky electrode disposed on a group III nitride semiconductor layer, a pad electrode disposed on the Schottky electrode and a solder disposed on the pad electrode and is capable of being mounted through the solder without degrading the semiconductor device properties, a mounted solder-containing semiconductor device, a producing method of the solder-containing semiconductor device and a mounting method thereof.

### BRIEF DESCRIPTION OF DRAWINGS

FIG. 1 is a sectional view schematically depicting an example of a solder-containing semiconductor device according to the present invention;

FIG. 2 is a sectional view schematically depicting another example of a solder-containing semiconductor device according to the present invention;

FIG. 3 is a sectional view schematically depicting yet another example of a solder-containing semiconductor device according to the present invention;

FIG. 4 is a sectional view schematically depicting an example of a mounted solder-containing semiconductor device according to the present invention;

FIG. 5 is a sectional view schematically depicting another example of a mounted solder-containing semiconductor device according to the present invention;

FIG. 6 is a sectional view schematically depicting yet another example of a mounted solder-containing semiconductor device according to the present invention;

FIG. 7 provides sectional views schematically depicting an example of a producing method and a mounting method of a solder-containing semiconductor device according to the present invention;

FIG. 8 provides sectional views schematically depicting another example of a producing method and a mounting method of a solder-containing semiconductor device according to the present invention; and

FIG. 9 is a graph depicting a relationship between a withstand voltage of an unmounted solder-containing semiconductor device and a withstand voltage of a mounted solder-containing semiconductor device according to the present invention.

### DESCRIPTION OF EMBODIMENTS

### First Embodiment

### Solder-Containing Semiconductor Device

Referring to FIGS. 1 to 3, solder-containing semiconductor devices 1, 2A and 3 according to certain embodiments of the present invention include semiconductor devices 1D, 2AD and 3D, respectively. Each of semiconductor devices 1D, 2AD and 3D includes a substrate 10, at least one group III nitride semiconductor layer 20 disposed on substrate 10, a Schottky electrode 40 disposed on group III nitride semiconductor layer 20, and a pad electrode 50 disposed on Schottky electrode 40. Pad electrode 50 has a multi-layer structure including at least a Pt layer. Each of semiconductor devices 1D, 2AD and 3D further includes a solder 60 which has a melting point of 200 to 230° C. and is disposed on pad electrode 50 of the semiconductor device.

In each of solder-containing semiconductor devices 1, 2A and 3 of the present embodiment, since pad electrode 50 has a multi-layer structure including the Pt layer and is disposed on Schottky electrode 40, and solder 60 having a melting point of 200 to 230° C. is disposed on pad electrode 50 of each semiconductor device 1D, 2AD or 3D, it allows the solder-containing semiconductor device to be bonded to a package at a temperature of 200 to 230° C., thereby suppressing deterioration in Schottky electrode 40 caused by a stress originated in bonding the Pt layer included in pad electrode 50 and concentrated on an electrode edge of Schottky electrode 40. Accordingly, degradation in the semiconductor device properties of each solder-containing semiconductor device 1, 2A or 3 can be suppressed.

From the consideration of relaxing an electric field concentrated on an electrode edge of Schottky electrode 40, it is preferable that each solder-containing semiconductor device 1, 2A or 3 of the present embodiment further includes a dielectric layer 30 or 80 which is provided with an opening 30w or 80w and is disposed on group III nitride semiconductor layer 20, and it is preferable that Schottky electrode 40 is disposed on a portion of group III nitride semiconductor layer 20 which is positioned within opening 30w or 80w of dielectric layer 30 or 80.

In addition, from the consideration of preventing an electric current from leaking to a chip end face, it is further preferable that Schottky electrode 40 is disposed on a portion of group III nitride semiconductor layer 20 which is positioned within opening 30w of dielectric layer 30 and on a portion of dielectric layer 30 which is positioned in the vicinity of opening 30w (for example, within a distance of 100 μm from the edge of the opening).

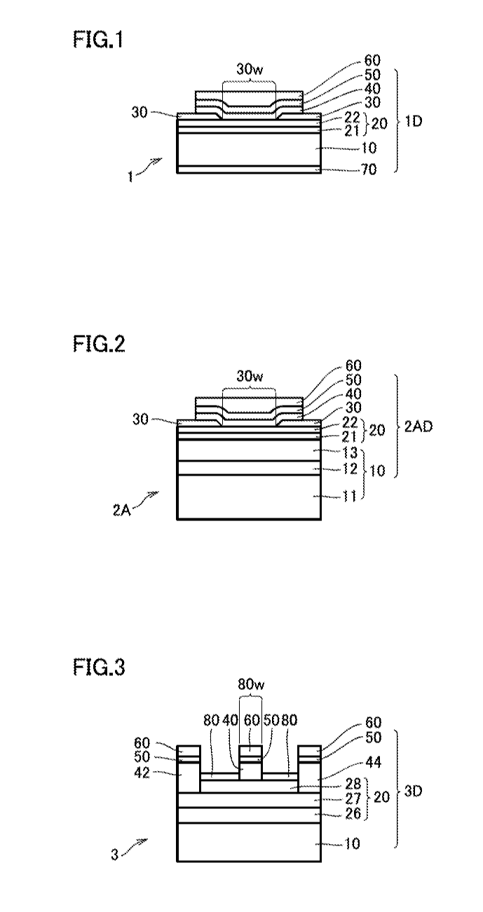

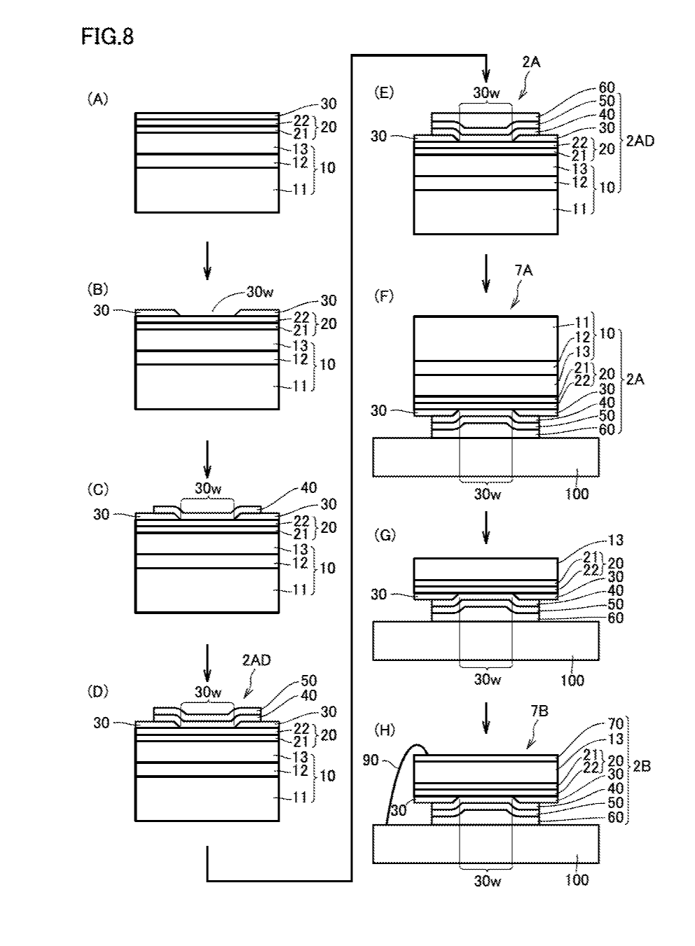

As depicted in FIG. 2, solder-containing semiconductor device 2A includes, as substrate 10, a composite substrate including an underlying substrate 11 and a group III nitride film 13 directly or indirectly bonded to underlying substrate 11. As depicted in FIG. 8, after solder-containing semiconductor device 2A including such a composite substrate is mounted by bonding solder 60 to a package, underlying substrate 11 is removed from the composite substrate, with group III nitride film 13 left as the substrate. Accordingly, a solder-containing semiconductor device 2B including group III nitride film 13 as the substrate is provided.

(Substrate)

Referring to FIGS. 1 to 3, substrate 10 is not particularly limited as long as it can support at least one group III nitride semiconductor layer 20 disposed thereon, and thereby, it may be a single substrate having a single-layer structure or a composite substrate having a multi-layer structure.

Referring to FIGS. 1 and 3, it is preferable that substrate 10 is a group III nitride substrate from the consideration that at least one group III nitride semiconductor layer 20 can be disposed thereon through growth.

Referring to FIG. 2, from the consideration of saving the whole cost of the substrate by reducing the amount of the expensive group III nitride, it is preferable that substrate 10 is a composite substrate including underlying substrate 11 and group III nitride film 13 directly or indirectly bonded to underlying substrate 11. Although underlying substrate 11 is not particularly limited as long as it can be directly or indirectly bonded to group III nitride film 13, from the consideration of saving the whole cost of the substrate, it is preferable that underlying substrate 11 is a Si substrate, a SiC substrate, a sapphire substrate, a composite oxide substrate (for example, Al₂O₃—SiO₂ based substrate such as mullite (3Al₂O₃.2SiO₂-2Al₂O₃.SiO₂) substrate, ZrO₂—Y₂O₃—Al₂O₃—SiO₂ based substrate such as YSZ (yttria-stabilized zirconia)-mullite substrate, or the like), or a polycrystalline substrate. Further, it is preferable that underlying substrate 11 is a composite oxide substrate due to the reason that a thermal expansion coefficient thereof may be controlled through the adjustment of its chemical composition.

From the consideration of improving bondability between underlying substrate 11 and group III nitride film 13, in the composite substrate as above, it is preferable that underlying substrate 11 and group III nitride film 13 are bonded to each other indirectly with a bonding film 12 interposed therebetween. Although bonding film 12 is not particularly limited, from the consideration of improving bondability between underlying substrate 11 and group III nitride film 13, it is preferable that bonding film 12 is a SiO₂ film, a Si₃N₄ film, or the like.

(Group III Nitride Semiconductor Layer)

Referring to FIGS. 1 to 3, group III nitride semiconductor layer 20 is not particularly limited as long as it is at least one group III nitride semiconductor layer 20 capable of making each solder-containing semiconductor device 1, 2A or 3 exhibit semiconductor device function and its composition may vary in accordance with the type of the solder-containing semiconductor device. Referring to FIGS. 1 and 2, in the case where each solder-containing semiconductor device 1 or 2A is a solder-containing SBD (Schottky Barrier Diode), group III nitride semiconductor layer 20 can include an n⁺-GaN layer 21 and an n⁻-GaN layer 22, for example. Referring to FIG. 3, in the case where solder-containing semiconductor device 3 is a solder-containing HEMT (High Electron Mobility Transistor), group III nitride semiconductor layer 20 can include a GaN layer 26, an n-Al₁₋ₓGaₓN layer 27 (0<x<1), and an n-GaN layer 28.

(Dielectric Layer Having an Opening)

Referring to FIGS. 1 to 3, although dielectric layer 30 or 80 having opening 30w or 80w is not particularly limited as long as it can improve the semiconductor device function of each solder-containing semiconductor device 1, 2A or 3, from the consideration of enhancing the reliability, it is preferable that the dielectric layer includes at least one silicon compound selected from the group consisting of Si₃N₄ and SiO₂, and it is preferable that the dielectric layer is at least one layer of a Si₃N₄ layer and a SiO₂ layer.

(Schottky Electrode)

Referring to FIGS. 1 to 3, although Schottky electrode 40 is not particularly limited as long as it is an electrode in Schottky contact with group III nitride semiconductor layer 20, from the consideration of the work function difference between the Schottky electrode and the group III nitride semiconductor layer, it is preferable that Schottky electrode 10 is an Ni/Au electrode (an electrode having a multilayer structure of an Ni layer and an Au layer disposed sequentially from the side of group III nitride semiconductor layer 20) or an Ni/Pd/Pt/Au electrode (an electrode having a multilayer structure of an Ni layer, a Pd layer, a Pt layer and an Au layer disposed sequentially from the side of group III nitride semiconductor layer 20), for example.

(Pad Electrode)

Referring to FIGS. 1 to 3, although pad electrode 50 is not particularly limited as long as it is an electrode which has a multilayer structure including a Pt layer and has a high bondability with Schottky electrode 40 and solder 60, from the consideration of using Au which has a good wettability to solder 60, it is preferable that pad electrode 50 is a Ti/Pt/Au electrode (an electrode having a multilayer structure of a Ti layer, a Pt layer and an Au layer disposed sequentially from the side of Schottky electrode 40) or an Ni/Pt/Au electrode (an electrode having a multilayer structure of an Ni layer, a Pt layer and an Au layer disposed sequentially from the side of Schottky electrode 40), for example.

From the consideration of effectively preventing the diffusion of Sn contained in solder 60, the thickness of the Pt layer provided in pad electrode 50 is preferably 30 nm or more, and more preferably 50 nm or more.

(Solder)

Referring to FIGS. 1 to 6, although solder 60 is not particularly limited as long as it has a melting point of 200 to 230° C. and has a high bondability with pad electrode 50 and a package 100, from the consideration of reducing stresses applied to the semiconductor device, it is preferable that solder 60 includes at least one alloy selected from the group consisting of Sn—Ag, Sn—Cu, Sn—Ag—Cu, Sn—In—Bi, Sn—Ag—Cu—Bi, and Sn—Ag—Bi—In. Specifically, an Sn—Ag solder, an Sn—Cu solder, an Sn—Ag—Cu solder, an Sn—In—Bi solder, an Sn—Ag—Cu—Bi solder, an Sn—Ag—Bi—In solder or the like may be given as an example of a suitable solder.

(Solder-Containing SBD)

Referring to FIG. 1, solder-containing semiconductor device 1 is an example of a solder-containing SBD, and includes substrate 10, group III nitride semiconductor layer 20 composed of n⁺-GaN layer 21 and n⁻-GaN layer 22 which are disposed sequentially on one main surface of substrate 10, dielectric layer 30 which is provided with opening 30w and is disposed on group III nitride semiconductor layer 20, Schottky electrode 40 which is disposed on a portion of group III nitride semiconductor layer 20 positioned within opening 30w of dielectric layer 30 and on a portion of dielectric layer 30 positioned in the vicinity of opening 30w, pad electrode 50 which is disposed on Schottky electrode 40, solder 60 which is disposed on pad electrode 50, and a substrate electrode 70 which is disposed on the other main surface of substrate 10.

Referring to FIG. 2, solder-containing semiconductor device 2A is another example of a solder-containing SBD, and includes substrate 10 which is a composite substrate including underlying substrate 11 and group III nitride film 13 directly or indirectly bonded to underlying substrate 11, group III nitride semiconductor layer 20 composed of n⁺-GaN layer 21 and n⁻-GaN layer 22 which are disposed sequentially on one main surface of substrate 10, dielectric layer 30 which is provided with opening 30w and is disposed on group III nitride semiconductor layer 20, Schottky electrode 40 which is disposed on a portion of group III nitride semiconductor layer 20 positioned within opening 30w of dielectric layer 30 and on a portion of dielectric layer 30 positioned in the vicinity of opening 30w, pad electrode 50 which is disposed on Schottky electrode 40, and solder 60 which is disposed on pad electrode 50.

Referring to FIG. 8, after solder-containing semiconductor device 2A mentioned above is mounted by bonding solder 60 to package 100, underlying substrate 11 is removed from the composite substrate serving as substrate 10, with group III nitride film 13 left as the substrate. Accordingly, solder-containing semiconductor device 2B including group III nitride film 13 as the substrate is provided.

(Solder-Containing HEMT)

Referring to FIG. 3, solder-containing semiconductor device 3 is an example of a solder-containing HEMT, and includes substrate 10, group III nitride semiconductor layer 20 composed of GaN layer 26, n-Al₁₋ₓGaₓN layer 27 (0<x<1) and n-GaN layer 28 which are disposed sequentially on one main surface of substrate 10, dielectric layer 80 which is provided with opening 80w and is disposed on group III nitride semiconductor layer 20, Schottky electrode 40 which is a gate electrode disposed on a portion of group III nitride semiconductor layer 20 positioned within opening 80w of dielectric layer 80, pad electrode 50 which is disposed on Schottky electrode 40, and solder 60 which is disposed on pad electrode 50. Solder-containing semiconductor device 3 further includes a source electrode 42 and a drain electrode 44 which are separate to each other and are provided on n-Al₁₋ₓGaₓN layer 27 of group III nitride semiconductor layer 20 exposed by removing a portion of dielectric layer 80 positioned on a portion of n-GaN layer 28 of group III nitride semiconductor layer 20 and then the portion of n-GaN layer 28, respectively, pad electrode 50 which is disposed on each of source electrode 42 and drain electrode 44, and solder 60 which is disposed on each of pad electrodes 50.

### Second Embodiment

### Mounted Solder-Containing Semiconductor Device

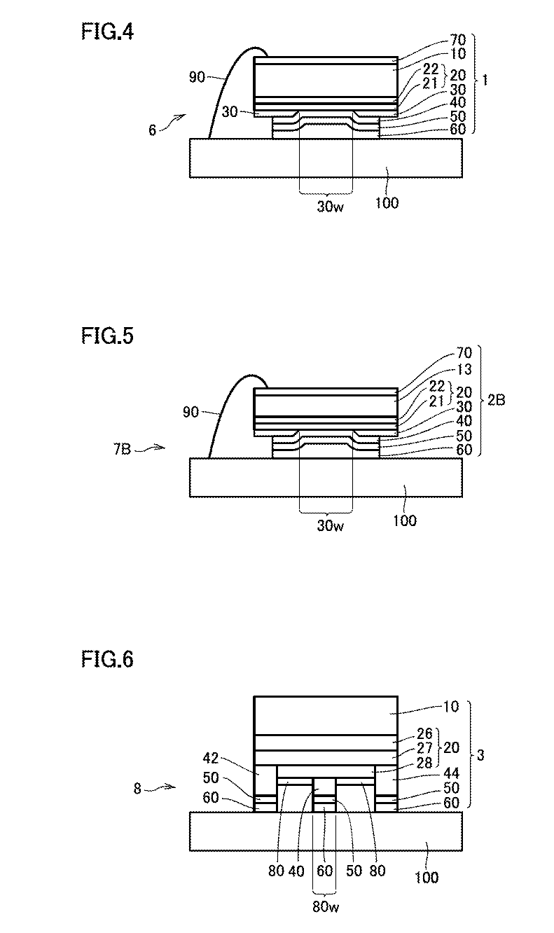

Referring to FIGS. 4 to 6, each of mounted solder-containing semiconductor devices 6, 7B and 8 according to another embodiment of the present invention is obtained by mounting each of solder-containing semiconductor devices 1, 2B and 3 according to the first embodiment to package 100 through bonding solder 60 in each of solder-containing semiconductor devices 1, 2B and 3 to package 100. In mounted solder-containing semiconductor device 6 or 7B according to the present embodiment, substrate electrode 70 of solder-containing semiconductor device 1 or 2B is connected to package 100 via a wire 90.

In each of mounted solder-containing semiconductor devices 6, 7B and 8 of the present embodiment, since each of solder-containing semiconductor devices 1, 2B and 3 is boned to package 100 at a temperature of 200 to 230° C., the deterioration in Schottky electrode 40 caused by a stress originated in bonding the Pt layer included in pad electrode 50 and concentrated on an electrode edge of Schottky electrode 40 is suppressed, and thus, the degradation in the semiconductor device properties of solder-containing semiconductor device 1, 2B or 3 is suppressed, and as a result, solder-containing semiconductor device 1, 2B or 3 has high semiconductor device properties.

(Package)

Package 100 is a substrate to which a semiconductor device is mounted. Package 100 is not particularly limited, but it preferably includes a conductive portion made of Cu, CuW or the like having a high heat dissipation property and an insulating portion made of epoxy resin, SiO₂ or the like.

### Third Embodiment

### Method for Producing Solder-Containing Semiconductor Device

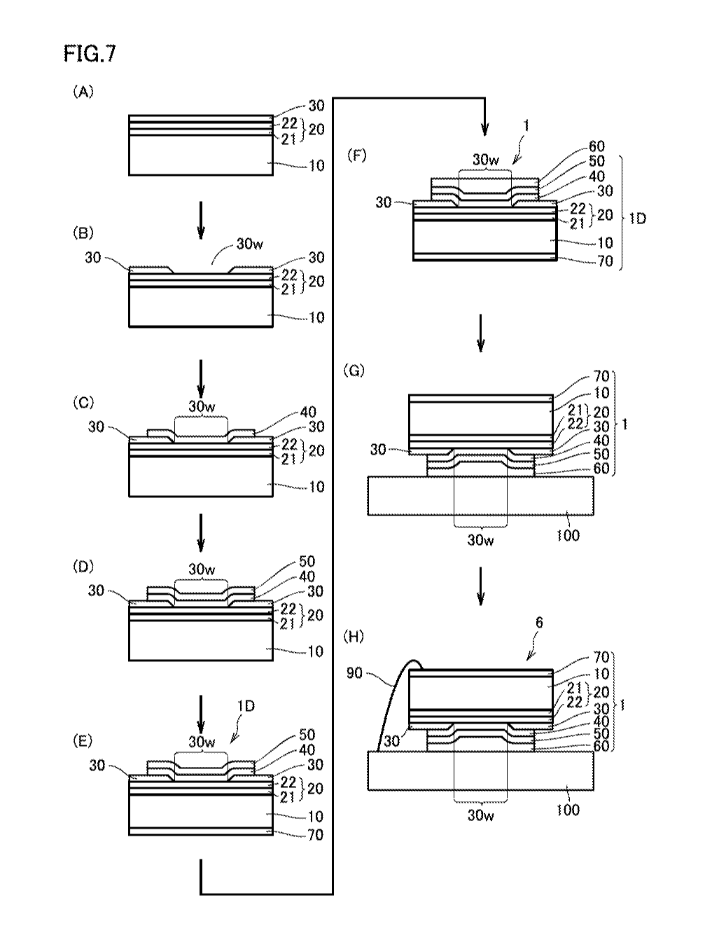

Referring to FIGS. 7 and 8, the method for producing solder-containing semiconductor device 1 or 2A according to yet another embodiment of the invention includes a step of forming semiconductor device 1D or 2AD. The step of forming semiconductor device 1D or 2AD includes a sub-step of forming at least one group III nitride semiconductor layer 20 on substrate 10, a sub-step of forming Schottky electrode 40 on group III nitride semiconductor layer 20, and a sub-step of forming pad electrode 50 on Schottky electrode 40. Pad electrode 50 has a multi-layer structure including at least a Pt layer. The method for producing solder-containing semiconductor device 1 or 2A according to yet another embodiment of the invention further includes a step of disposing solder 60 which has a melting point of 200 to 230° C. on pad electrode 50 of semiconductor device 1D or 2AD.

According to the method for producing solder-containing semiconductor device 1 or 2A of the present embodiment, the degradation in the semiconductor device properties of solder-containing semiconductor device 1 or 2A in mounting it to the package is suppressed, and thereby, it is possible to produce efficiently solder-containing semiconductor device 1 or 2A, from which a mounted solder-containing semiconductor device having high semiconductor device properties can be obtained.

Form the consideration that dielectric layer 30 relaxes the electric field concentrated on an electrode edge of Schottky electrode 40, it is preferable that the method for producing solder-containing semiconductor device 1 or 2A of the present embodiment further includes a sub-step of forming dielectric layer 30 having opening 30w on group III nitride semiconductor layer 20, which is performed after the sub-step of forming group III nitride semiconductor layer 20 and before the sub-step of forming Schottky electrode 40, and in the sub-step of forming Schottky electrode 40, Schottky electrode 40 is formed on a portion of group III nitride semiconductor layer 20 that is positioned within opening 30w of dielectric layer 30.

In addition, from the consideration of preventing an electric current from leaking to a chip end face, it is preferable that in the step of forming Schottky electrode 40, Schottky electrode 40 is formed on a portion of group III nitride semiconductor layer 20 which is positioned within opening 30w of dielectric layer 30 and on a portion of dielectric layer 30 which is positioned in the vicinity of opening 30w (for example, within a distance of 100 μm from the edge of the opening).

(Step of Forming Semiconductor Device)

Referring to FIGS. 7 and 8, the method for producing solder-containing semiconductor device 1 or 2A according to the present embodiment includes a step of forming semiconductor device 1D or 2AD. The step of forming semiconductor device 1D or 2AD includes a sub-step of forming at least one group III nitride semiconductor layer 20 on substrate 10 (see FIGS. 7(A) and 8(A)), a sub-step of forming Schottky electrode 40 on group III nitride semiconductor layer 20 (see FIGS. 7(C) and 8(C)), and a sub-step of forming pad electrode 50 on Schottky electrode 40 (see FIGS. 7(D) and 8(D)). Preferably, the step of forming semiconductor device 1D or 2AD further includes a sub-step of forming dielectric layer 30 having opening 30w on group III nitride semiconductor layer 20 (see FIGS. 7(B) and 8(B)), which is performed after the sub-step of forming group III nitride semiconductor layer 20 (see FIGS. 7(A) and 8(A)) and before the sub-step of forming Schottky electrode 40 (see FIGS. 7(C) and 8(C)).

Referring to FIGS. 7(A) and 8(A), although the method for forming group III nitride semiconductor layer 20 is not particularly limited in the sub-step of forming at least one group III nitride semiconductor layer 20 on one main surface of substrate 10, from the consideration of growing group III nitride semiconductor layer 20 of a high crystal quality, as a vapor phase growth method, HVPE (hydride vapor phase epitaxy) method, MOCVD (Metal Organic Chemical Vapor Phase Deposition) method, MBE (Molecular Beam Epitaxy) method, a sublimation method or the like is preferred, and as a liquid phase growth method, a high pressure nitrogen liquid method, a flux method or the like is preferred.

From the consideration of growing group III nitride semiconductor layer 20 of a high crystal quality, it is preferable that substrate 10 is a group III nitride substrate. Furthermore, from the consideration of saving the whole cost of the substrate by reducing the amount of the expensive group III nitride, it is preferable that substrate 10 is a composite substrate including underlying substrate 11 and group III nitride film 13 directly or indirectly bonded to underlying substrate 11.

Referring to FIGS. 7(B) and 8(B), although the sub-step of forming dielectric layer 30 having opening 30w on group III nitride semiconductor layer 20 is not particularly limited, from the consideration of efficiently forming dielectric layer 30 having opening 30w, it is preferable that after forming dielectric layer 30 on group III nitride semiconductor layer 20, opening 30w is formed by removing a portion of dielectric layer 30. The method for forming dielectric layer 30 is not particularly limited as long as it is a growth method suitable for the material of dielectric layer 30, for example, a magnetron sputtering method, an ECR (Electron Cyclotron Resonance) sputtering method, an EB (e-beam) vapor-deposition method or the like is preferable. The method for forming opening 30w in dielectric layer 30 is not particularly limited as long as it is suitable for the material of dielectric layer 30, for example, a wet etching method or the like is preferable.

Referring to FIGS. 7(C) and 8(C), in the sub-step of forming Schottky electrode 40 on group III nitride semiconductor layer 20, or on a portion of group III nitride semiconductor layer 20 which is positioned within opening 30w of dielectric layer 30, or on a portion of group III nitride semiconductor layer 20 which is positioned within opening 30w of dielectric layer 30 and a portion of dielectric layer 30 which is positioned in the vicinity of opening 30w (for example, within a distance of 100 μm from the edge of the opening), the method for forming Schottky electrode 40 is not particularly limited as long as it is suitable for the material of Schottky electrode 40, for example, an EB vapor-deposition method or the like is preferable.

Referring to FIGS. 7(D) and 8(D), in the step forming pad electrode 50 on Schottky electrode 40, the method for forming pad electrode 50 is not particularly limited as long as it is suitable for the material of pad electrode 50, for example, an EB vapor-deposition method and followed by lift-off process or the like is preferable. From the consideration of preventing the diffusion of Sn contained in solder 60, pad electrode 50 has a multilayer structure including a Pt layer.

In addition, referring to FIG. 7(E), the producing method of solder-containing semiconductor device 1 may include a sub-step of forming substrate electrode 70 on the other main surface of substrate 10 after the sub-step of forming pad electrode 50. The method for forming substrate electrode 70 is not particularly limited as long as it is suitable for the material of substrate electrode 70, for example, an EB vapor-deposition method or the like is preferable. Accordingly, semiconductor device 1D can be obtained efficiently.

(Step of Disposing Solder)

Referring to FIGS. 7(F) and 8(E), although solder 60 is not particularly limited in the step of disposing solder 60 having a melting point of 200 to 230° C. on pad electrode 50 of each of semiconductor devices 1D and 2AD, from the consideration of reducing the stress applied to the semiconductor device, it is preferable that solder 60 includes at least one alloy selected from the group consisting of Sn—Ag, Sn—Cu, Sn—Ag—Cu, Sn—In—Bi, Sn—Ag—Cu—Bi, and Sn—Ag—Bi—In. Accordingly, solder-containing semiconductor devices 1 and 2A can be obtained efficiently.

### Fourth Embodiment

### Mounting Method of Solder-Containing Semiconductor Device

Referring to FIGS. 7 and 8, the mounting method of solder-containing semiconductor device 1 or 2A according to yet another embodiment of the present invention includes a step of providing solder-containing semiconductor device 1 or 2A of the first embodiment (see FIGS. 7(A) to 7(E) and FIGS. 8(A) to 8(E)) and a step of bonding solder 60 of solder-containing semiconductor device 1 or 2A to package 100 at a temperature of 200 to 230° C. so as to mount solder-containing semiconductor device 1 or 2A (see FIGS. 7(G) to 7(H) and FIGS. 8(F) to 8(H)).

According to the method for mounting solder-containing semiconductor device 1 or 2A of the present embodiment, since the degradation in the semiconductor device properties of solder-containing semiconductor device 1 or 2A in mounting it to the package is suppressed, it is possible to obtain mounted solder-containing semiconductor device 6, 7A or 7B having high semiconductor device properties.

Referring to FIG. 8, from the consideration of improving the heat dissipation property of the semiconductor device while reducing the cost thereof, it is preferable that the method for mounting solder-containing semiconductor device 2A according to the present embodiment includes a step of providing solder-containing semiconductor device 2A (see FIGS. 8(A) to 8(E)), a step of bonding solder 60 of solder-containing semiconductor device 2A to package 100 so as to mount solder-containing semiconductor device 2A (see FIG. 8(F)), and a step of removing underlying substrate 11 from the composite substrate serving as substrate 10 of solder-containing semiconductor device 2A (see FIGS. 8(F) and 8(G)). According to the mounting method, it is possible to mount solder-containing semiconductor device 2B including group III nitride film 13 as the substrate to package 100 so as to provide mounted solder-containing semiconductor device 7B which has high semiconductor device properties and high temperature operation properties.

(Preparing Solder-Containing Semiconductor Device)

Referring FIGS. 7(A) to 7(F) and FIGS. 8(A) to 8(E), since the step of preparing solder-containing semiconductor device 1 or 2A is the same as that in the producing method of solder-containing semiconductor device 1 or 2A according to the third embodiment, the description thereof will not be repeated.

(Mounting Solder-Containing Semiconductor Device)

Referring FIGS. 7(G) and 8(F), the step of mounting solder-containing semiconductor device 1 or 2A is performed by bonding solder 60 of solder-containing semiconductor device 1 or 2A to package 100 at a temperature of 200 to 230° C.

Referring to FIG. 7(H), in the case of solder-containing semiconductor device 1, substrate electrode 70 of solder-containing semiconductor device 1 is connected to package 100 through wire 90 to provide mounted solder-containing semiconductor device 6.

(Removing Underlying Substrate from Composite Substrate of Solder-Containing Semiconductor Device)

Referring to FIGS. 8(F) and 8(G), in the case of mounted solder-containing semiconductor device 7A obtained by bonding solder-containing semiconductor device 2A to package 100, it is possible to include a step of removing underlying substrate 11 from the composite substrate serving as substrate 10 of solder-containing semiconductor device 2A. If the composite substrate serving as substrate 10 includes bonding film 12, it is also possible to remove bonding film 12. The method for removing underlying substrate 11 and bonding film 12 is not particularly limited, and thus, any method such as cutting, machining, grinding or etching may be used. The etching may be wet etching in which an etchant is used or dry etching such as RIE (Reactive Ion Etching).

Referring to FIGS. 8(G) and 8(H), in the case of mounting solder-containing semiconductor device 7A, as described above, underlying substrate 11 and bonding film 12 are removed from the composite substrate serving as substrate 10 of solder-containing semiconductor device 2A to expose group III nitride film 13, and solder-containing semiconductor device 2B is obtained by forming substrate electrode 70 on the exposed group III nitride film 13. The method for forming substrate electrode 70 is not particularly limited as long as it is suitable for the material of the substrate electrode 70, for example, an EB vapor-deposition method or the like is preferable. Then, referring to FIG. 8(H), mounted solder-containing semiconductor device 7B can be obtained by connecting substrate electrode 70 of solder-containing semiconductor device 2B to package 100 by wire 90.

### EXAMPLES

### Example 1

### 1. Preparation of Solder-Containing Semiconductor Device

Referring to FIG. 7(A), n⁺-GaN layer 21 (carrier concentration: 2×10¹⁸ cm⁻³) of 3 μm in thickness and n⁻-GaN layer 22 (carrier concentration: 5×10¹⁵ cm⁻³) of 5 μm in thickness were grown sequentially according to the MOCVD (Metal Organic Chemical Vapor Deposition) method as group III nitride semiconductor layer 20 on one main surface of a GaN substrate, which serves as substrate 10, of 2 inches (5.08 cm) in diameter and 400 μm in thickness.

Next, referring to FIG. 7(B), after a Si₃N₄ layer of 1 μm in thickness was formed according to the sputtering method as dielectric layer 30 on n⁻-GaN layer 22 of group III nitride semiconductor layer 20, opening 30w of 1000 μm in diameter was formed according to the etching method.

Next, referring to FIG. 7(C), an Ni/Au electrode was formed as Schottky electrode 40 by sequentially depositing an Ni layer of 100 nm in thickness and an Au layer of 500 nm in thickness according to the EB vapor deposition method on a portion of group III nitride semiconductor layer 20 which is positioned within opening 30w of dielectric layer 30 and on a portion of dielectric layer 30 which is positioned in the vicinity of opening 30w (within a distance of 100 μm from the edge of the opening).

Next, referring to FIG. 7(D), a Ti/Pt/Au electrode was formed as pad electrode 50 by sequentially depositing a Ti layer of 50 nm in thickness, a Pt layer of 100 nm in thickness and an Au layer of 2 μm in thickness according to the EB vapor deposition method on Schottky electrode 40.

Next, referring to 7(E), an Al/Ti/Au electrode was formed as substrate electrode 70 by sequentially depositing an Al layer of 200 nm in thickness, a Ti layer of 50 nm in thickness and an Au layer of 500 nm in thickness according to the EB vapor deposition method on the other main surface of substrate 10, and was made into a chip having dimensions of 2 mm×2 mm by scribbling and breaking. Then, an Sn—Ag solder (Sn content is 97 wt % and Ag content is 3 wt % in the solder) having a melting point of 210° C. was disposed on pad electrode 50 as solder 60.

In the manner as described above, a chip of solder-containing semiconductor device 1 was obtained. The withstand voltage was measured for each of the solder-containing semiconductor devices 1. The withstand voltage of each unmounted solder-containing semiconductor device was taken as a reverse voltage at which the leakage current in Schottky electrode 40 is 1×10⁻³ A/cm².

### 2. Mounting of Solder-Containing Semiconductor Device

Next, referring to FIG. 7(G), solder 60 of solder-containing semiconductor device 1 was bonded to package 100 at a temperature of 230° C.

Next, referring to FIG. 7(H), substrate electrode 70 of solder-containing semiconductor device 1 was connected to package 100 through wire 90 made of Au.

In the manner as described above, mounted solder-containing semiconductor device soldered chip 6 was obtained by mounting the chip of solder-containing semiconductor device 1 to package 100. The withstand voltage was measured for each of the mounted solder-containing semiconductor devices. The withstand voltage for the mounted solder-containing semiconductor device was measured by the same criteria as the withstand voltage for the unmounted solder-containing semiconductor device.

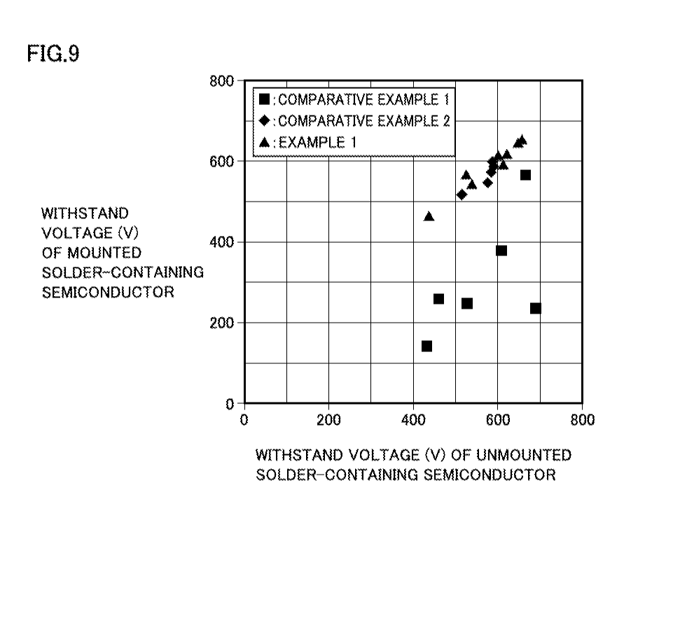

The withstand voltages for solder-containing semiconductor devices 1 before and after they were mounted were plotted in the graph of FIG. 9.

### Comparative Example 1

Except that an Au—Sn solder (Au content is 80 wt % and Sn content is 20 wt % in the solder) having a melting point of 280° C. was used as the solder, and the solder was bonded to the package at a temperature of 340° C., the solder-containing semiconductor device was prepared and mounted to the package in the same manner as in Example 1, and the withstand voltages for the mounted solder-containing semiconductor device and the unmouned solder-containing semiconductor device were measured and plotted in the graph of FIG. 9.

### Comparative Example 2

Except that a Ti/Au electrode without a Pt layer was formed as the pad electrode by depositing sequentially a Ti layer of 50 nm in thickness and an Au layer of 2 μm in thickness, an Au—Sn solder (Au content is 80 wt % and Sn content is 20 wt % in the solder) having a melting point of 280° C. was used as the solder, and the solder was bonded to the package at a temperature of 340° C., the solder-containing semiconductor device was prepared and mounted to the package in the same manner as in Example 1, and the withstand voltages for the mounted solder-containing semiconductor device and the unmouned solder-containing semiconductor device were measured and plotted in the graph of FIG. 9.

Referring to FIG. 9, as shown by Comparative Example 2, even though the solder-containing semiconductor device which does not include a Pt layer in the pad electrode is bonded to the package through the solder disposed on the pad electrode at a temperature of 340° C., the withstand voltage for the mounted solder-containing semiconductor device does not decrease in comparison with the withstand voltage for the unmounted solder-containing semiconductor device. However, since Sn is in ohmic contact with the n-type GaN, there occurs a problem that the Schottky characteristic is deteriorated by the diffusion of Sn in the solder. Thus, it is necessary to include a Pt layer in the pad electrode.

As shown by Comparative Example 1, in the case where the solder-containing semiconductor device which includes a Pt layer in the pad electrode is bonded to the package through the solder disposed on the pad electrode at a temperature of 340° C., the withstand voltage for the mounted solder-containing semiconductor device significantly decreases in comparison with the withstand voltage for the unmounted solder-containing semiconductor device.

In contrast, as shown by Example 1, in the case where the solder-containing semiconductor device which includes a Pt layer in the pad electrode is bonded to the package through the solder disposed on the pad electrode at a temperature of 230° C., the withstand voltage for the mounted solder-containing semiconductor device does not decrease in comparison with the withstand voltage for the unmounted solder-containing semiconductor device, and maintains high voltage-withstanding performance.

It should be understood that the embodiments disclosed herein have been presented for the purpose of illustration and description but not limited in all aspects. It is intended that the scope of the present invention is not limited to the description above but defined by the scope of the claims and encompasses all modifications equivalent in meaning and scope to the claims.

### REFERENCE SIGNS LIST

1, 2A, 2B, 3: solder-containing semiconductor device; 1D, 2AD, 2BD, 3D: semiconductor device; 6, 7A, 7B, 8: mounted solder-containing semiconductor device; 10: substrate; 11: underlying substrate; 12: bonding film; 13: group III nitride film; 20: group III nitride semiconductor layer; 21: n⁺-GaN layer; 22: n⁻-GaN layer; 26: GaN layer; 27: n-Al₁₋ₓGaₓN layer; 28: n-GaN layer; 30, 80: dielectric layer; 30w, 80w: opening; 40: Schottky electrode; 42: source electrode; 44: drain electrode; 50: pad electrode; 60: solder; 70: substrate electrode; 90: wire; 100: package

1. A solder-containing semiconductor device comprising a semiconductor device,
the semiconductor device including:
a substrate;
at least one group III nitride semiconductor layer disposed on said substrate;
a Schottky electrode disposed on said group III nitride semiconductor layer; and
a pad electrode disposed on said Schottky electrode,
said pad electrode having a multi-layer structure including at least a Pt layer,
the solder-containing semiconductor device further comprising a solder having a melting point of 200 to 230° C. and being disposed on said pad electrode of said semiconductor device.

2. The solder-containing semiconductor device according to claim 1, wherein
said solder-containing semiconductor device further includes a dielectric layer having an opening and being disposed on said group III nitride semiconductor layer, and
said Schottky electrode is disposed on a portion of said group III nitride semiconductor layer that is positioned within said opening of said dielectric layer.

3. The solder-containing semiconductor device according to claim 1, wherein
said substrate is a group III nitride substrate.

4. The solder-containing semiconductor device according to claim 1, wherein
said substrate is a composite substrate including an underlying substrate and a group III nitride film directly or indirectly bonded to said underlying substrate.

5. The solder-containing semiconductor device according to claim 4, wherein
said solder-containing semiconductor device includes said group III nitride film left from said composite substrate after the removal of said underlying substrate as said substrate.

6. The solder-containing semiconductor device according to claim 1, wherein
said solder includes at least one alloy selected from the group consisting of Sn—Ag, Sn—Cu, Sn—Ag—Cu, Sn—In—Bi, Sn—Ag—Cu—Bi, and Sn—Ag—Bi—In.

7. The solder-containing semiconductor device according to claim 1, wherein
said Pt layer has a thickness of 30 nm or more.

8. The solder-containing semiconductor device according to claim 2, wherein
said dielectric layer includes at least one silicon compound selected from the group consisting of Si₃N₄ and SiO₂.

9. A mounted solder-containing semiconductor device, comprising a solder-containing semiconductor device according to claim 1, wherein
said solder-containing semiconductor device is mounted to a package by bonding said solder of said solder-containing semiconductor device to said package.

10. A method for producing a solder-containing semiconductor device,
comprising a step of forming a semiconductor device,
the step of forming a semiconductor device including:
a sub-step of forming at least one group III nitride semiconductor layer on a substrate;
a sub-step of forming a Schottky electrode on said group III nitride semiconductor layer; and
a sub-step of forming a pad electrode on said Schottky electrode,
said pad electrode having a multi-layer structure including at least a Pt layer,
the method further comprising a step of disposing a solder having a melting point of 200 to 230° C. on said pad electrode of said semiconductor device.

11. The method for producing a solder-containing semiconductor device according to claim 10, wherein
the step of forming a semiconductor device further includes a sub-step of forming a dielectric layer having an opening on said group III nitride semiconductor layer, which is performed after the sub-step of forming said group III nitride semiconductor layer and before the sub-step of forming said Schottky electrode, and
said Schottky electrode is formed in the sub-step of forming said Schottky electrode on a portion of said group III nitride semiconductor layer that is positioned within said opening of said dielectric layer.

12. A method for mounting a solder-containing semiconductor device, comprising the steps of:
preparing a solder-containing semiconductor device according to claim 1; and
bonding said solder of said solder-containing semiconductor device to a package at a temperature of 200 to 230° C. so as to mount said solder-containing semiconductor device.

13. A method for mounting a solder-containing semiconductor device,
comprising the steps of:
preparing a solder-containing semiconductor device according to claim 4;
bonding said solder of said solder-containing semiconductor device to a package at a temperature of 200 to 230° C. so as to mount said solder-containing semiconductor device; and
removing said underlying substrate from said composite substrate of said solder-containing semiconductor device.
